(19) United States
(12) Patent Application Publication
(10) Pub. No.: US 2024/0403183 A1
(43) Pub. Date: Dec. 5, 2024

(54) Error Factor Estimation Device, Error Factor Estimation Method, and Computer-Readable Medium

(71) Applicant: Hitachi High-Tech Corporation, Minato-ku, Tokyo (JP)

(72) Inventors: Yasuhiro YOSHIDA, Tokyo (JP); Masayoshi ISHIKAWA, Tokyo (JP); Fumihiro SASAJIMA, Tokyo (JP); Shigeo OKOSHI, Tokyo (JP)

(21) Appl. No.: 18/698,452

(22) PCT Filed: Oct. 29, 2021
(86) PCT No.: PCT/JP2021/040062

§ 371 Date: Apr. 4, 2024

(51) Int. Cl. G06F 11/32; G06F 11/30

(52) U.S. Cl. CPC G06F 11/324; G06F 11/3072

(57) ABSTRACT

This error factor estimation device 100 is a device for estimating the error factor of errors that occur, and comprises: a feature-quantity-group-generating unit A2a that processes data including inspection results collected from an inspection device and generates a plurality of feature quantities; a model-generating unit 4 that generates a model A5a for learning the relationship between the plurality of feature quantities generated by the feature-quantity-group-generating unit A2a and errors; a contribution-degree-calculating unit 11 that calculates a contribution degree indicating the degree of contribution to the output of the model A5a for at least one of the plurality of feature quantities used for the model A5a learning; and an error factor acquisition unit 15 that acquires error factors labeled with feature quantities selected on the basis of the usefulness calculated from the contribution degree calculated by the contribution-degree-calculating unit 11.

### TECHNICAL FIELD

The present invention relates to an error factor estimation device, an error factor estimation method, and a computer-readable medium for estimating an error factor of an occurring error.

### BACKGROUND ART

Semiconductor inspection devices execute inspection operations or measurement operations for each of inspection points on surfaces of semiconductor wafers in accordance with setting parameters called recipes. In the adjustment of the recipes, engineers generally optimize items by manual work depending on the attributes of an inspection target and the characteristics of a device, and the like. Accordingly, for example, when recipes of which adjustment is not sufficient are used, inspection results are likely to be errors in inspection operations. On the other hand, unlike such errors originated from such recipes, inspection results become erroneous due to hardware aging or malfunctions. When errors occur, engineers correct recipes for recipe-induced errors and exchange components deteriorated over time for hardware-induced errors or maintain malfunctioning components. In this way, since countermeasures taken against error factors are different, it is very important to estimate the effort factors.

In estimation of error factors, a classification scheme by machine training or the like is used (for example, see PTL 1). PTL 1 discloses a technique for increasing the amount of fault data by causing a circuit to generate training data for common fault data or causing a process to generate training data for common fault data.

### CITATION LIST

### Patent Literature

PTL 1: JP2012-199338A

### SUMMARY OF INVENTION

### Technical Problem

Various causes such as a change in a recipe, update of a device component, and a change in an inspection target result in data drift in which a trend of data changes continuously or discontinuously. When the data drift occurs, formulation of estimation of error factors obtained by training past inspection results is not suitable for new inspection results. Accordingly, it is difficult for a classification model for training a relationship between error factors and past inspection results to classify present inspection results subject to data drift into error factors.

An object of the present disclosure is to provide a technique capable of estimating an error factor of an occurring error even when data drift in which an inspection result changes continuously or discontinuously occurs.

### Solution to Problem

To solve the foregoing problem, according to an aspect of the present disclosure, an error factor estimation device that estimates an error factor of an inspection result which becomes erroneous includes: a computer system including one processor or a plurality of processors and one memory or a plurality of memories, wherein the computer system executes a first feature generating process of processing data including the inspection result collected from an inspection device and generating a plurality of feature quantities, a model generating process of generating a first model for training a relationship between errors and the plurality of feature quantities generated through the first feature generating process, a contribution degree calculating process of calculating a contribution degree indicating the degree of contribution of at least one of the plurality of feature quantities used for training for the first model to an output of the first model, and an error factor acquisition process of acquiring error factors labeled with feature quantities or combinations of the feature quantities selected based on the contribution degree calculated through the contribution degree calculating process or usefulness calculated from the contribution degree.

### Advantageous Effects of Invention

According to the present disclosure, it is possible to estimate an error factor of an occurring error even when data drift in which inspection results change continuously or discontinuously occurs.

Other problems, configurations, and advantageous effects will be classified in description of the following embodiments.

### BRIEF DESCRIPTION OF DRAWINGS

FIG. 1 is a block diagram illustrating an overall configuration of an error factor estimation device according to Example 1.

FIG. 2 is a hardware block diagram illustrating a computer system of the error factor estimation device.

FIG. 3 is a diagram illustrating data structures of feature groups A and B.

FIG. 4 is a diagram illustrating inspection results for each inspection ID and a diagram illustrating feature quantities for each inspection ID.

FIG. 5 is a diagram illustrating a selection screen for selecting feature quantities defined in a feature quantity list.

FIG. 6 is a diagram illustrating a training method for detection rules of error records.

FIG. 7 is a block diagram illustrating details of an error factor estimation unit.

FIG. 8 is a diagram illustrating a calculation method for usefulness of feature quantities.

FIG. 9 is a screen illustrating an analysis result displayed on an output device.

FIG. 10 is a flowchart illustrating an error factor estimation method.

FIG. 11 is a block diagram illustrating details of an error factor estimation unit according to Example 2.

FIG. 12 is a flowchart illustrating an error factor estimation method according to Example 2.

FIG. 13 is a diagram illustrating a data structure of an error dictionary according to Example 2.

FIG. 14 is a block diagram illustrating details of a model generating unit according to Example 3.

FIG. 15 is a diagram illustrating an estimation result of an error probability by an error probability estimation unit according to Example 3.

FIG. 16 is a flowchart illustrating a use example of an error factor estimation device according to Example 4.

### DESCRIPTION OF EMBODIMENTS

In embodiments to be described below, “semiconductor inspection devices” include a device that measures dimensions of a pattern formed on a surface of a semiconductor wafer, a device that inspects whether there is a defect of a pattern formed on a surface of a semiconductor wafer, a device that inspects whether there is a defect of a bare wafer on which a pattern is not formed, and a combined device that these devices are combined.

In the embodiments to be described below, the term “inspection” is used in the sense of measurement or inspection, and the term “inspection operation” is used in the sense of a measurement operation or an inspection operation. In the embodiments to be described below, the term “inspection target” is used to indicate a measurement or inspection target wafer or a measurement or inspection target region in the wafer. In the embodiments to be described below, the term “error” includes a measurement failure, a device failure, and an error indication such as an alert or a warning message.

### Example 1

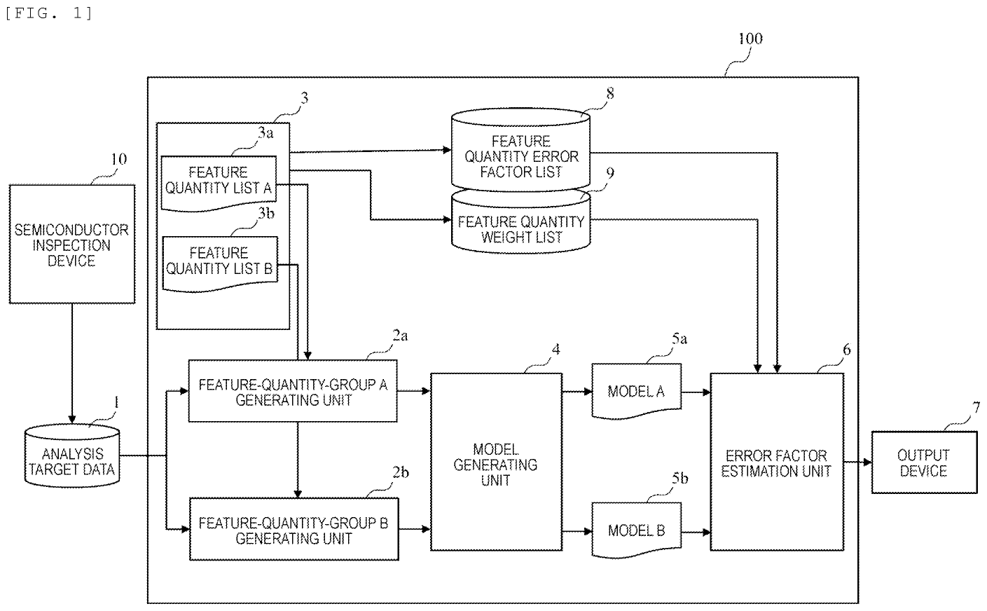

An error factor estimation device 100 according to Example 1 will be described with reference to FIG. 1. The error factor estimation device 100 according to Example 1 estimates an error factor of an inspection result that becomes erroneous (hereinafter appropriately referred to as error data) in a semiconductor inspection device 10. The semiconductor inspection device 10 executes an inspection operation for each inspection point on a surface of a semiconductor wafer in accordance with a setting parameter called a recipe. The error factor estimation device 100 may be an on-premise device administrated: in a facility managed by a user of the semiconductor inspection device 10 or may be a cloud administrated by a facility managed by the user of the semiconductor inspection device 10. The error factor estimation device 100 may be embedded in the semiconductor inspection device 10. The error factor estimation device 100 includes a feature-quantity-group A generating unit 2a, a feature-quantity-group B generating unit 2b, a feature quantity list storage unit 3 that stores feature quantity lists A3a and B3b, a model generating unit 4, a model A5a, a model B5b, an error factor estimation unit 6, a feature quantity error factor list 8, and a feature quantity weight list 9. The error factor estimation device 100 according to Example 1 includes two feature-quantity-group generating units (2a and 2b), two feature quantity lists (A3a and B3b), and two models (A5a and B5b). The error factor estimation device 100 may include three feature groups, three feature quantity lists, and three models.

### (Analysis Target Data 1)

The analysis target data 1 is data collected from the semiconductor inspection device 10. In the analysis target data 1 input to the error factor estimation device 100, an inspection result of the semiconductor inspection device 10 is stored, including error data for which an error factor is desired to be analyzed. The inspection result is stored in the analysis target data 1 in association with an inspection ID, device data, a recipe, and presence or absence of an error. The analysis target data 1 may be stored in an internal storage of the semiconductor inspection device 10 or may be stored in an external storage connected to be able to communicate with the semiconductor inspection device 10.

The inspection ID is a number given whenever an inspection target is inspected by the semiconductor inspection device 10 and is a number for identifying an inspection result.

The device data includes a deice-unique parameter, individual difference correction data, and an observation condition parameter. The deice-unique parameter is a correction parameter used to cause the semiconductor inspection device 10 to operate: in accordance with specification definitions. The individual difference correction data is a parameter used to correct an individual difference between the semiconductor inspection devices 10. The observation condition parameter is, for example, a parameter for defining an observation condition of a scanning electron microscope (SEM) such as an acceleration voltage of an electron optical system.

The recipe includes a wafer map, a pattern matching image, an alignment parameter, an addressing parameter, and a length measurement parameter. The wafer map is a coordinate map (for example, coordinates of a pattern) on a semiconductor wafer. The pattern matching image is a searched image used to detect measurement coordinates. The alignment parameter is, for example, a parameter used to correct a deviation between a coordinate system on a semiconductor wafer and a coordinate system inside the semiconductor inspection device 10. The addressing parameter is, example, information for specifying a characteristic pattern which is within an inspection target region in a pattern formed on a semiconductor wafer. The length measurement parameter is a parameter for describing a condition for measurement of a length and a parameter for designating a portion of which a length is to be measured.

An inspection result includes a length measurement, image data, and an operation log. The length measurement result is information regarding a length of a pattern on a semiconductor wafer. The image data is an observation image of semiconductor wafer. The operation log is data for describing an inner state of the semiconductor inspection device 10 in each operation process such as alignment, addressing, and length measurement and includes, for example, an operation voltage of each component and coordinates of an observation visual field. A change in an internal environment of the semiconductor inspection device 10, such as a change in a recipe or update of a device component or a change in an external environment of the semiconductor inspection device 10, such as a change in an inspection target in data drift in which a trend of an inspection result of the semiconductor inspection device 10 changes continuously or discontinuously.

The presence or absence of an error is a parameter indicating whether error data representing that an inspection result is an error is normal data representing normality. This parameter may indicate a process in which an error occurs during each operation process such as alignment, addressing, and length measurement.

### (Hardware Configuration of Error Factor Estimation Device 100)

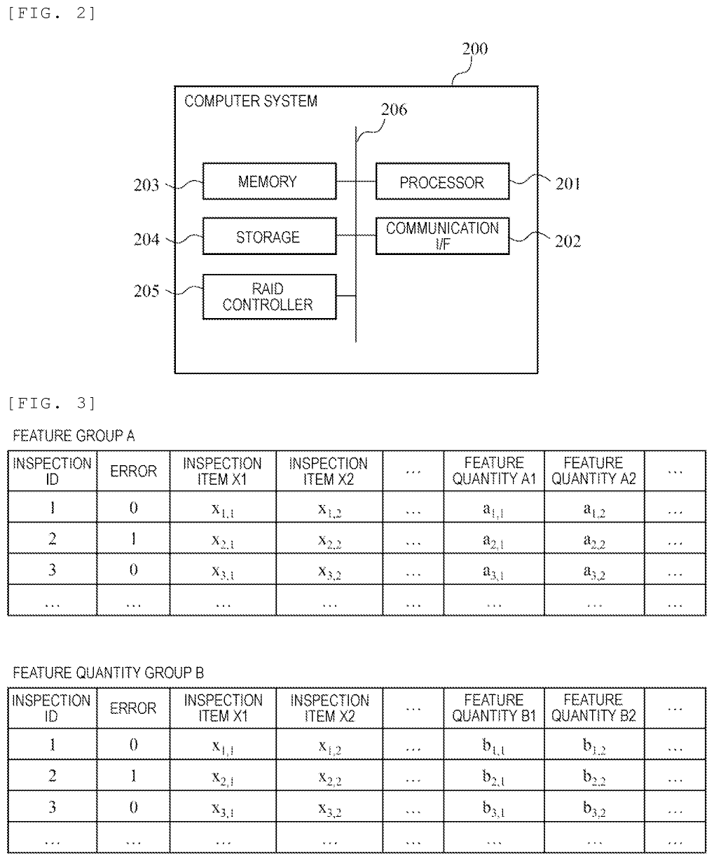

The error factor estimation device 100 includes a computer system 200 that includes one processor or a plurality of processors and one memory or a plurality of memories. The computer system 200 functions as the feature-quantity-group A generating unit 2a, the feature-quantity-group B generating unit 2b, the feature quantity list storage unit 3, the model generating unit 4, the model A5a, the model B5b, the error factor estimation unit 6, the feature quantity error factor list 8, and the feature quantity weight list 9 illustrated in FIG. 1. The computer system 200 executes each process of the flowchart of FIG. 10 to be described below. FIG. 2 is a diagram illustrating a hardware configuration of the computer system 200. A hardware configuration of the computer system 200 will be described with reference to FIG. 2.

The computer system 200 includes a processor 201, a communication interface 202 (hereinafter abbreviated to an I/F), a memory 203, a storage 204, a RAID controller 205, and a bus 206 connecting the above modules to be able to communicate with each other. The processor 201 executes a program command for executing each process of the flowchart of FIG. 10. The processor 201 is, for example, a central processing unit (CPU), a digital signal processor (DSP), an application specific integrated circuit (ASIC), or the like. The processor 201 loads a program command stored in the storage 204 in a work area of the memory 203 so that the program can be executed. The memory 203 stores a program command executed by the processor 201, data processed by the processor 201, and the like. The memory 203 is a flash memory, a random access memory (RAM), a read only memory (ROM), or the like. The storage 204 stores an OS, a boot program, and a web application. The storage 204 stores the above feature quantity lists A3a and B3b, feature groups A and B to be described below, the models A5a and B5b, the feature quantity error factor list 8, and the feature quantity weight list 9. The storage 204 is a hard disk drive (HDD), a solid state drive (SSD), or the like.

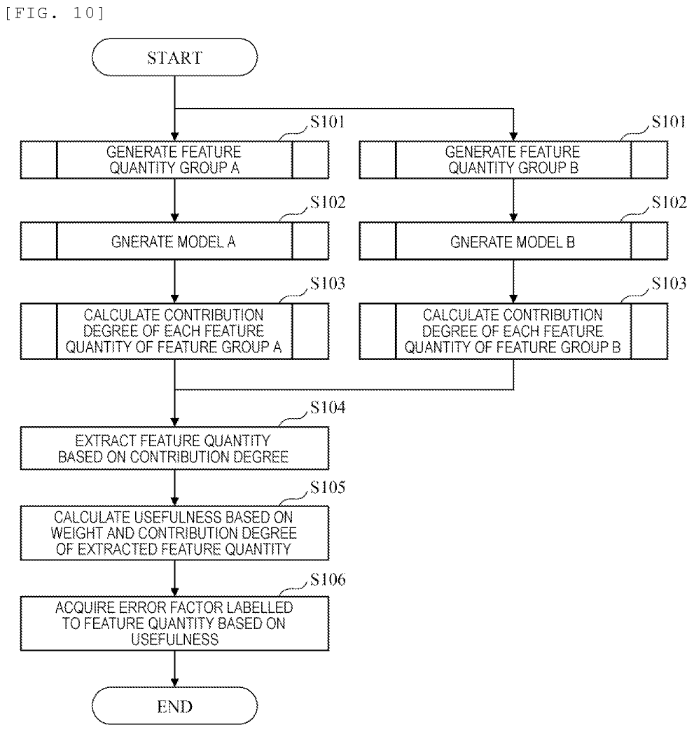

A communication I/F 202 is connected to be able to communicate with a storage that stores the above analysis target data 1 and receives the analysis target data 1 from the storage. The communication I/F 202 outputs an analysis result 900 (see FIG. 9) to the output device 7 locally or on a network. The RAID controller 205 logically administrates the plurality of storages 204 as one device. The RAID controller 205 writes various types of data in the plurality of storages 204 and reads various types of data from the plurality of storages 204.

### (Feature Group Generating Unit)

The feature-quantity-group A generating unit 2a processes the analysis target data 1 to generate one or more feature quantities.

The one or more feature quantities generated by the feature-quantity-group A generating unit 2a are referred to as a feature group A. The feature quantities generated by the feature-quantity-group A generating unit 2a are defined in the feature quantity list A3a. The feature-quantity-group B generating unit 2b processes the analysis target data 1 to generate one or more feature quantities. The one or more feature quantities generated by the feature-quantity-group B generating unit 2b are referred to as a feature group B. The feature quantities generated by the feature-quantity-group B generating unit 2b are defined in the feature quantity list B3b.

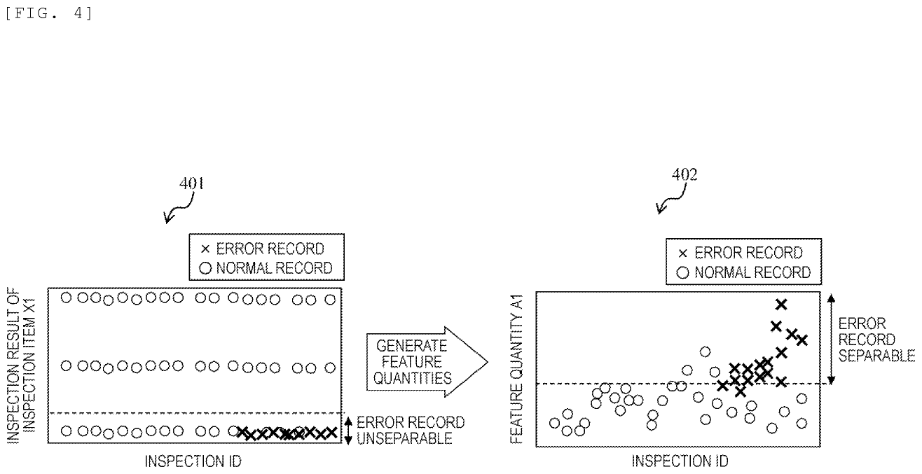

The above feature groups A and B will be described with reference to FIG. 3. Whenever the semiconductor inspection device 10 inspects an inspection target, an inspection ID is allocated and recipe inspection results (X1,1, X1,2, . . . ) are recorded for the inspection ID. The feature-quantity-group A generating unit 2a processes the analysis target data 1 to generate feature quantities A1 and A2, and the like defined in the feature quantity list A3a. The feature-quantity-group B generating unit 2b processes the analysis target data 1 to generate feature quantities B1 and B2, and the like defined in the feature quantity list B3b.

### (Examples of Feature Quantities)

Next, specific examples of the feature quantities will be described.

The feature quantity is an index related to a variation in an inspection result in the same device. The feature quantity is a difference between an inspection result and a median or an average of the inspection results in the same device with regard to a certain inspection item.

Another feature quantity is, for example, an index related to a variation in an inspection result at the same measurement point. The feature quantity is a difference between an inspection result and a median or an average of inspection results of the same measurement point with regard to a certain inspection item.

Still another feature quantity is, for example, an index related to a variation in an inspection result in the same recipe. The feature quantity is a difference between an inspection result and a median or an average of inspection results of the same recipe with regard to a certain inspection item.

Still another feature quantity is, for example, an index related to a variation in an inspection result in the same wafer. The feature quantity is a difference between an inspection result and a median or an average of inspection results in the same wafer with regard to a certain inspection item.

Still another feature quantity is, for example, an index related to a variation in an inspection result in a measurement point at which a reference image for the same pattern matching. The feature quantity is a difference between an inspection result and a median or an average of inspection results in the measurement point at which the reference image for the same pattern matching with regard to a certain inspection item.

Still another feature quantity can be a feature quantity set as, for example, an error rate for a specific device or specific coordinates.

### (Inspection Result and Feature Amount)

Comparison between an inspection result for a certain inspection item and a feature quantity generated by processing the inspection result will be described with reference to FIG. 4. In FIG. 4, a circle mark indicates a normal record and an X mark indicates an error record. The left drawing of FIG. 4 is a diagram 401 in which inspection results of an inspection item X1 are plotted for each inspection ID. The right drawing of FIG. 4 is a diagram 402 in which feature quantities A1 are plotted for each inspection ID. In the left diagram 401 of FIG. 4, normal records and error records of raw data (inspection results) of the inspection item X1 coexist within the same range, and thus it is difficult to determine a threshold and distinguish the error records from the normal records. In the right diagram 402 of FIG. 4, however, by generating feature quantities which are an index related to a variation in the inspection results, as described above, it is possible to determine a threshold and distinguish the error records from the normal records. When the feature quantity and an error factor have a close relation, a threshold for distinguishing the error records originating from an error factor having a close relation with the feature quantity by plotting the feature quantities for each inspection ID is determined as in the right diagram 402 of FIG. 4.

### (Feature Quantity List Storage Unit 3)

The feature quantity list storage unit 3 stores the feature quantity list A3a and the feature quantity list B3b. The feature quantity list A3a defines one feature quantity or a plurality of feature quantities generated by the feature-quantity-group A generating unit 2a. That is, the feature-quantity-group A generating unit 2a generates one feature quantity or a plurality of feature quantities defined in the feature quantity list A3a. The feature quantity list B3b defines one feature quantity or a plurality of feature quantities generated by the feature-quantity-group B generating unit 2b. That is, the feature-quantity-group B generating unit 2b generates one feature quantity or a plurality of feature quantities defined in the feature quantity list B3b.

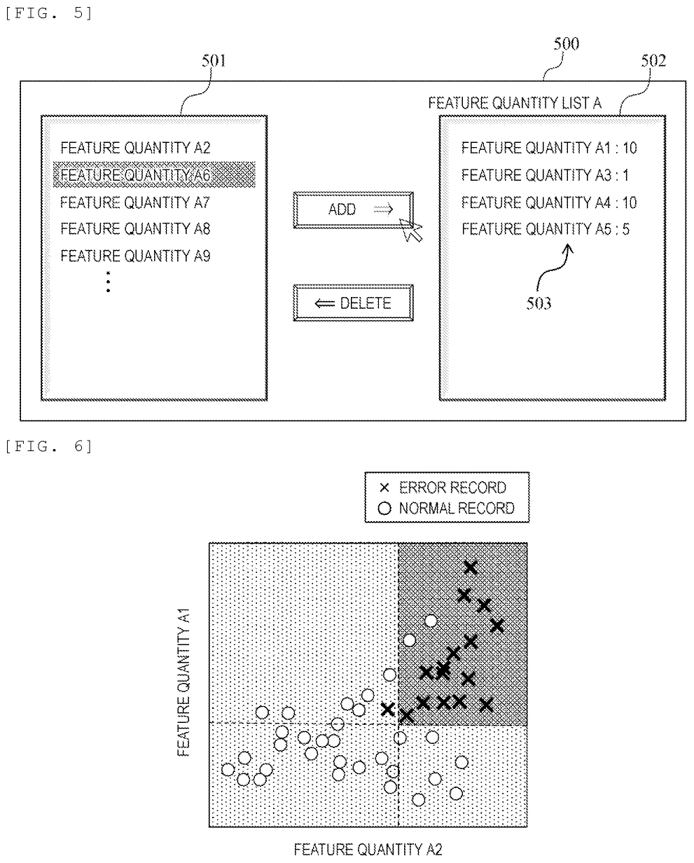

Any feature quantities defined in the feature quantity lists A3a and B3b can be selected by a user. FIG. 5 is a diagram illustrating a selection screen 500 for selecting the feature quantities. The user can select the feature quantities for each of the feature quantity lists A3a and B3b. The user selects any feature quantity from a feature quantity list 501 of the selection screen 500 and adds the feature quantity to a feature quantity list field 502. The feature quantities displayed in the feature quantity list field 502 are feature quantities defined in the feature quantity list A3a. The user can also select and delete a feature quantity added to the feature quantity list field 502. The computer system 200 executes a selection process of selecting a plurality of feature quantities generated by the feature-quantity-group A generating unit 2a and the feature-quantity-group B generating unit 2b in response to an instruction from the user. The user sets a weight 503 in each feature quantity of the feature quantity list field 502. The weight 503 set in each feature quantity is stored in the feature quantity weight list 9 for each feature quantity.

The user can select a combination of feature quantities appropriate for estimating an error factor through the selection screen 500. The selection screen 500 may be displayed on a display unit of the output device 7 or may be displayed on a display unit connected to the error factor estimation device 100. For example, the selection screen 500 may be a screen provided by a web application executed in the error factor estimation device 100, and a web browser of the output device 7 displays the selection screen 500 provided from the web application. That is, the web application executed in the error factor estimation device 100 executes a display control process to display the selection screen 500 on the display unit of the output device 7.

For example, when a hardware-induced error is ascertained as an error factor, a feature quantity which is a difference between an inspection result and a median or an average of inspection results in the above same device in the feature quantity list A3a is defined. When a recipe factor error is ascertained as an error factor, a feature quantity which is a difference between an inspection result and a median or an average of inspection results in the above same recipe in the feature quantity list B3b is defined. That is, the user defines one feature quantity or a plurality of feature quantities related to a hardware-induced error in the feature quantity list A3a and defines one feature quantity or a plurality of feature quantities related to a recipe-induced error in the feature quantity list B3b. Since the feature quantities defined in the feature quantity lists A3a and B3b are any feature quantities, feature quantities related to the recipe-induced error may be defined in the feature quantity list A3a or feature quantities related to the hardware-induced error may be defined in the feature quantity list B3b. Feature quantities common to both the feature quantity lists A3a and B3b may be defined.

### (Feature Quantity Error Factor List 8)

In the feature quantity error factor list 8, feature quantities labeled with error factors are stored. In the feature quantity error factor list 8, for example, a hardware-induced error is labeled to a feature quantity which is a difference between an inspection result and a median or an average of the inspection results in the same device. In the feature quantity error factor list 8, for example, a recipe-induced error is labeled to a feature quantity which is a difference between an inspection result and a median or an average of the inspection results in the same recipe. The error factors may be not only a hardware-induced error or a recipe-induced error but also detailed error factors such as fault portions of a device and inappropriate recipe parameters.

### (Feature Quantity Weight List 9)

In the feature quantity weight list 9, the feature quantities are stored in association with weights set in the feature quantities. The weights set in the feature quantities are weights set in the feature quantity list field 502 of the selection screen 500. The weights stored in the feature quantity weight list 9 are set in accordance with magnitude of the relation with the error factors. The weights are values used when usefulness to be described below is calculated. As defaults of the weights, values adjusted in another site can be used.

### (Model Generating Unit 4)

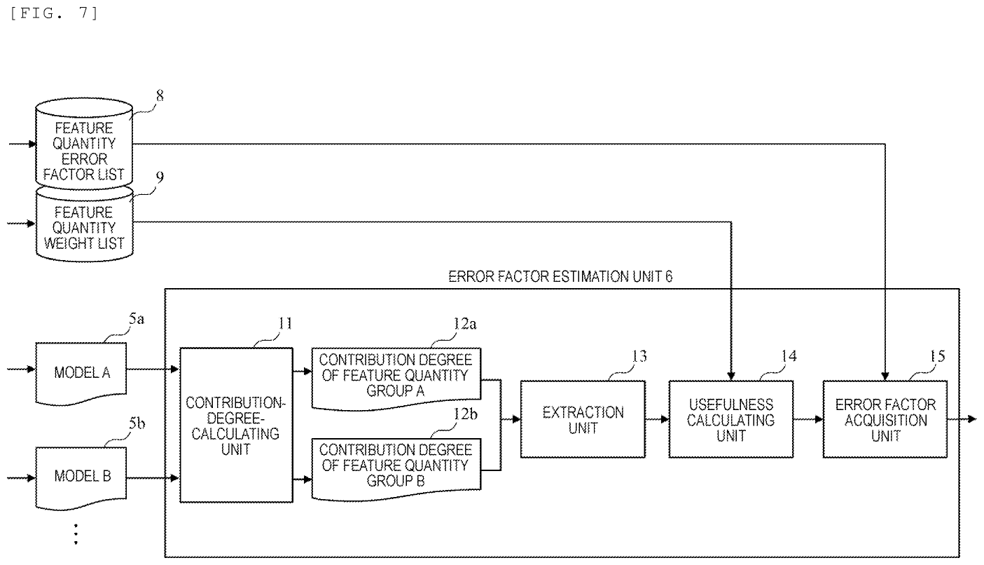

The model generating unit 4 generates the models A5a and B5b for training the relationship with the plurality of feature quantities and errors. A model trained with the feature quantities of the feature quantity group A generated by the feature-quantity-group A generating unit 2a is set as the model A5a, and a model trained with the feature quantities of the feature quantity group B generated by the feature-quantity-group B generating unit 2b is set as the model B5b. The models A5a and B5b are constructed using an algorithm in which a decision tree such as Random Forest or Gradient Boosting Tree is based or a machine training algorithm such as Neural Network. FIG. 6 illustrates an image of a training method when the models are constructed by an algorithm in which decision tree is based. The models are models for training a classification method of classifying the error records and the normal records using feature quantities of an input feature quantity group. FIG. 6 illustrates an example in which a classification method of classifying the error records and the normal records using the feature quantities A1 and A2 is trained.

### (Error Factor Estimation Unit 6)

The error factor estimation unit 6 calculates usefulness of each feature quantity for error prediction results of the models A5a and B5b and estimates error factors based on the usefulness. The error factor estimation unit 6 estimates error factors of error data based on the feature quantity error factor list 8 and the feature quantity weight list 9. As illustrated in FIG. 7, the error factor estimation unit 6 includes a contribution-degree-calculating unit 11, an extraction unit 13, a usefulness calculating unit 14, and an error factor acquisition unit 15.

### (Contribution-Degree-Calculating Unit 11)

The contribution-degree-calculating unit 11 calculates a contribution degree indicating the degree of contribution of each feature of the feature quantity group A used for training the model A5a to an error prediction result which is an output of the model A5a. The contribution-degree-calculating unit 11 calculates a contribution degree indicating the degree of contribution of each feature of the feature quantity group B used for training the model B5b to an error prediction result which is an output of the model B5b. For example, when a model is constructed by an algorithm in which a decision tree is based, the contribution degree is a variable importance (Feature Importance) calculated based on the number of feature quantities appearing in branches of a model, an improvement value of an objective function, or the like. The contribution-degree-calculating unit 11 may calculate a contribution degree using sensitivity analysis for a model s Shapley additive explanations (SHAP) or a feature quantity selection algorithm. In this way, the contribution-degree-calculating unit 11 calculates a contribution degree of each feature quantity of the feature quantity group A used for training the model A5a (hereinafter referred to as a contribution degree 12a of the feature quantity group A) and calculates a contribution degree of each feature quantity of the feature quantity group B used for training the model B5b (hereinafter referred to as a contribution degree 12b of the feature quantity group B).

### (Extraction Unit 13)

The extraction unit 13 extracts one feature quantity or a plurality of feature quantities based on the contribution degree calculated by the contribution-degree-calculating unit 11. The extraction unit 13 may extract high-order N (where N is a predetermined number) feature quantities with high a contribution degree or may extract feature quantities with contribution degrees equal to or greater than a predetermined threshold. For combinations of the feature quantities extracted by the extraction unit 13, for example, all the high-order N feature quantities can belong to the feature quantity group A in some cases irrespective of affiliation of the feature quantity groups A and B.

### (Usefulness Calculating Unit 14)

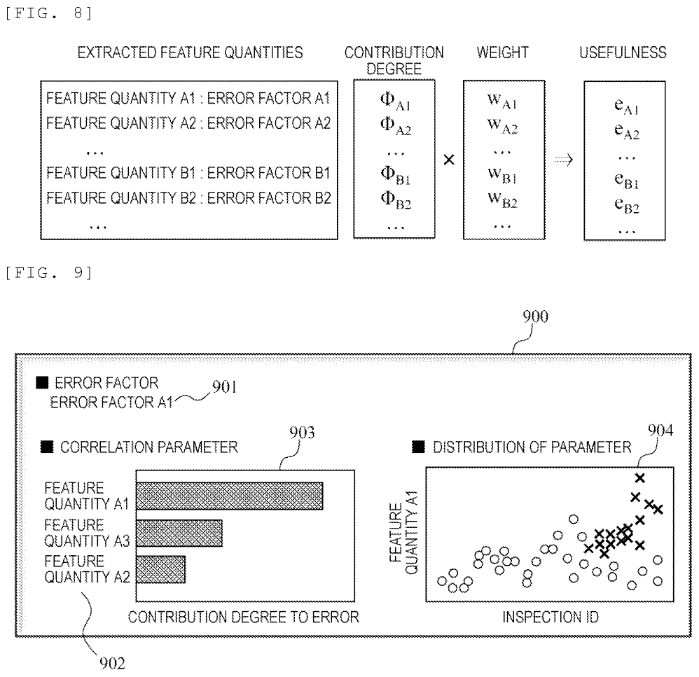

The usefulness calculating unit 14 calculates usefulness of each feature quantity extracted by the extraction unit 13 based on a contribution degree of the feature amount and a weight of the feature quantity. The usefulness is used to estimate an error factor. As illustrated in FIG. 8, the usefulness is calculated by multiplying a contribution degree ϕ of the feature quantity and a weight w of the feature quantity. Usefulness e may be calculated based on the contribution degree ϕ of the feature quantity and the weight w of the feature quantity, and a calculating method is not limited to the multiplication of the contribution degree ϕ of the feature quantity and the weight w of the feature quantity.

### (Error Factor Acquisition Unit 15)

The error factor acquisition unit 15 selects one feature quantity or a plurality of feature quantities based on the usefulness calculated by the usefulness calculating unit 14 and acquires an error factor labeled to the selected feature quantity. For example, the error factor acquisition unit 15 acquires an error factor labeled to a feature quantity with the highest usefulness with reference to the feature quantity error factor list 8. The error factor acquisition unit 15 may acquire error factors labeled to high-order M (here M is a predetermined number) feature quantities with high usefulness. The error factor acquisition unit 15 transmits the analysis result 900 to the output device 7. As illustrated in FIG. 9, the analysis result 900 includes acquired error factors 901, high-order M feature quantities 902 with high usefulness, contribution degrees 903 of the feature quantities, and a diagram 904 in which the feature quantities (the feature quantities with highest usefulness) are plotted for each inspection ID.

### (Output Device 7)

The output device 7 is a display device, and receives and displays the analysis result 900 transmitted by the error factor acquisition unit 15. Specifically, as illustrated in FIG. 9, the output device 7 displays the error factors 901, the high-order M feature quantities 902 with high usefulness, the contribution degrees 903 of the feature quantities, and the diagram 904 in which the feature quantities (the feature quantities with highest usefulness) are plotted for each inspection ID so that the user can recognize them. When the error factor acquisition unit 15 acquires the error factor labeled to the high-order M feature quantities with high usefulness, the output device 7 may display the error factors as candidates for the error factors in a usefulness order. The output device 7 may be a device locally connected to the error factor estimation device 100 or may be a device connected to a network. The contribution degrees 903 may be usefulness.

### (Error Factor Estimation Method)

Next, details of the error factor estimation method executed by the error factor estimation device 100 will be described with reference to FIG. 10. Each step of the flowchart illustrated in FIG. 10 is executed by the computer system 200 functioning as the feature-quantity-group A generating unit 2a, the feature-quantity-group B generating unit 2b, the model generating unit 4, and the error factor estimation unit 6. A program command for executing the error factor estimation method is stored in a non-transitory computer-readable medium, for example, the storage 204.

The computer system 200 (the feature-quantity-group A generating unit 2a and the feature-quantity-group B generating unit 2b) generates the feature quantity group A including the feature quantities defined in the feature quantity list A3a and the feature quantity group B including the feature quantities defined in the feature amount list B3b (S101 [a first feature quantity generating process and a second feature quantity generating process]). Subsequently, the computer system 200 (the model generating unit 4) generates the model A5a trained with the feature quantities of the feature quantity group A and the model B5b trained with the feature quantities of the feature quantity group B (S102 [a model generating process]). Then, the computer system 200 (the contribution-degree-calculating unit 11) calculates a contribution degree of each feature quantity of the feature quantity group A and a contribution degree of each feature quantity of the feature quantity group B (S103 [a contribution degree calculating process]).

Subsequently, the computer system 200 (the extraction unit 13) extracts one feature quantity or a plurality of feature quantities based on the contribution degree calculated in S103 (S104 [an extraction process]). Subsequently, the computer system 200 (the usefulness calculating unit 14) calculates the usefulness of each feature quantity extracted by the extraction unit 13 (S105 [a usefulness calculating process]). The usefulness is calculated based on the contribution degree of the feature quantity and the weight of the feature quantity. Then, the computer system 200 (the error factor acquisition unit 15) selects one feature quantity or a plurality of feature quantities based on the usefulness and acquires an error factor labeled to the selected feature quantity with reference to the feature quantity error factor list 8 (S106 [an error factor acquisition process]). The computer system 200 transmits the analysis result 900 to the output device 7. Accordingly, the output device 7 displays the diagram 904 in which the error factor 901, the high-order M feature quantities 902 of usefulness, the contribution degrees 903 of the feature quantities, and the feature quantity (the feature quantity with highest usefulness) for each ID are plotted so that the user can recognize them.

### Advantageous Effects According to Example 1

In a general classification model in which many pieces of error data labeled with the error factors are prepared and the relationship between the error data and the error factors is trained, countermeasures against data drift in which an error occurrence tendency changes continuously or discontinuously cannot be taken. Accordingly, in Example 1, the error factors labeled to the feature quantities selected based on the usefulness are acquired with reference to the feature quantity error factor list 8. Accordingly, even when the data drift in which the trend of the error data changes occurs, the error factors can be estimated by labeling the error factors to the feature quantities responding to errors unless the feature quantities are changed.

Further, in Example 1, by labeling the error factors to the feature quantities, it is possible to considerably reduce the number of processes necessary for the labeling in comparison with a general scheme for labeling error factors to error data.

In Example 1, by preparing the feature quantity error factor list 8 for storing the feature quantities labeled with the error factors, it is possible to easily acquire the error factors from the feature quantities selected based on the usefulness.

Further, in Example 1, the usefulness of the feature quantities is calculated based on the weights of the feature quantities set in accordance with the magnitude of the relation between the contribution degree of each feature quantity and the error factor. Accordingly, since the weights set in accordance with the magnitude of the relation with the error factors can be taken into account to specify an error factor, the error factor of the high relation with the error factor is acquired, and thus estimation accuracy of the error factors is improved.

In Example 1, by calculating the usefulness of the feature quantities extracted by the extraction unit 13, it is possible to reduce a calculation load related to the calculation of the usefulness compared with a case in which the usefulness of all the feature quantities is calculated.

When feature quantities commonly responding to the plurality of error factors are mixed, the feature quantities helpful for specifying the error factors such as a hardware-induced error or a recipe-induced error are not used for training the model. Accordingly, by grouping the feature quantity groups generated in accordance with a situation desired to be ascertained, such as a hardware-induced error or a recipe-induced error, the feature quantities helpful for specifying the error factors are used to train the model. As a result, since the error factors labeled to the feature quantities can be acquired, estimation accuracy of the error factors is improved.

By displaying the selection screen 500 for selecting the feature quantities generated by the feature-quantity-group A generating unit 2a and the feature-quantity-group B generating unit 2b, an engineer or the like can select the feature quantities considered to be related to the error factors in the list of the feature quantities. As a result, since the feature quantities considered to be unrelated to the error factors can be excluded in advance, estimation accuracy of the error factors is improved.

Further, in Example 1, the user can ascertain the error factors of the error data by confirming a screen displayed by the output device 7. The user can confirm that the extracted feature quantities are correlated to errors and validity of the estimated error factors by confirming the trend and confirm the feature quantities contributing to the estimation of the error factors. Accordingly, the user can correct the recipe with sense of understanding when an estimated error is a recipe-induced error, and can take countermeasures such as maintenance with sense of understanding when an estimated error is a hardware-induced error.

By training the threshold for classifying the error records and the normal records using the plurality of feature quantities in the models A5a and B5b in Example 1, it is possible to easily acquire the feature quantities contributing to an output of an error measurement result.

In Example 1, by using the index related to a variation in the inspection results as the feature quantities, it is possible to estimate the error factors even if the data drift occurs in the inspection result and the index related to the variation can be affected by the data drift.

### Example 2

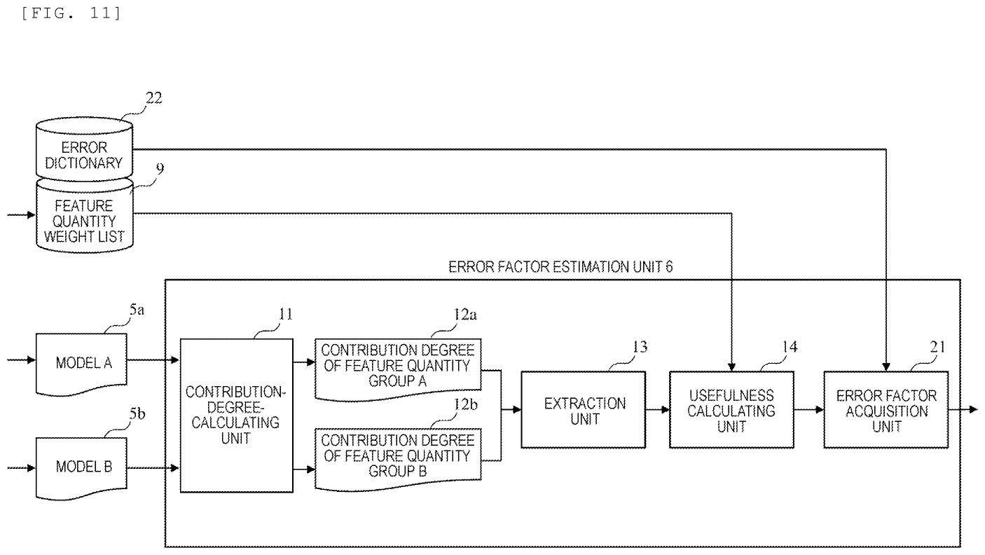

An error factor estimation device 100 according to Example 2 will be described with reference to FIGS. 11 to 13. As illustrated in FIG. 11, the error factor estimation device 100 according to Example 1 includes the feature quantity error factor list 8 and the error factor acquisition unit 15 acquiring the error factors with reference to the feature quantity error factor list 8. On the other hand, the error factor estimation device 100 according to Example 2 includes an error dictionary 22 and an error factor acquisition unit 21 that acquires error factors with reference to the error dictionary 22.

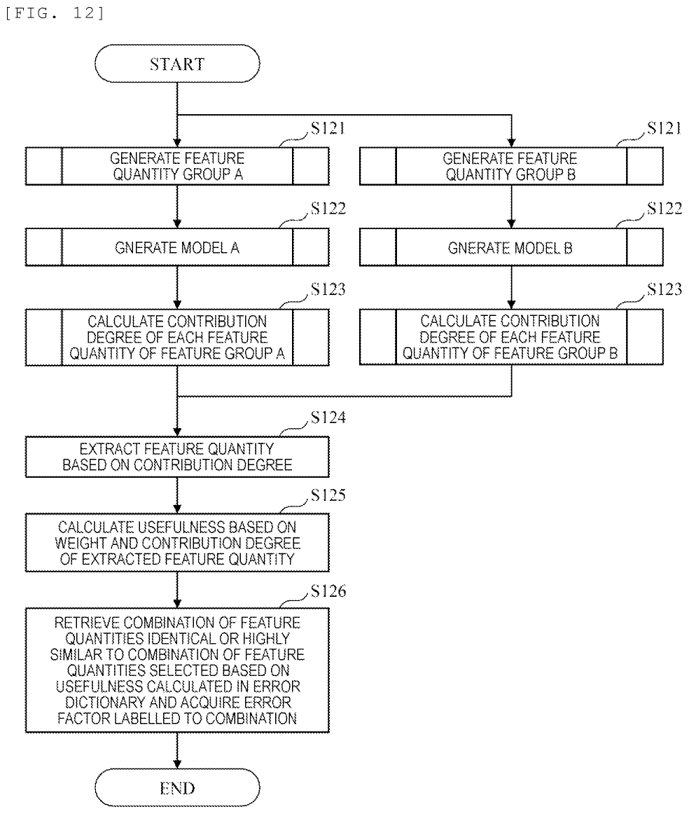

Next, an error factor estimation method by the error factor estimation device 100 according to Example 2 will be described with reference to FIG. 12. S121 to S125 of FIG. 12 are similar to the processes of S101 to S105 of FIG. 10 according to Example 1, and thus description thereof will be omitted.

The error factor acquisition unit 21 retrieves a combination of feature quantities identical or highly similar to the combination of the feature quantities selected based on the usefulness calculated by the usefulness calculating unit 14 in the error dictionary 22 and acquires error factors labeled with the combination (S126).

Here, a data structure of the error dictionary 22 will be described with reference to FIG. 13. In each row of the error dictionary 22, combinations of feature quantities labeled with the error factors are recorded. In FIG. 13, 1 indicates a value of a feature quantity related to an error factor and 0 indicates a feature quantity unrelated to an error factor. The feature quantities related to the error factors may be defined with values in the range of 0 to 1 in accordance with importance. In this case, in the error dictionary 22, a combination of feature quantities with the importance highly similar to values of the usefulness of the feature quantities may be retrieved. As a retrieving method, for example, collaborative filtering can be used. The error factor acquisition unit 21 acquires the error factors labeled to the combinations of the feature quantities retrieved in this way. The error factors acquired here may be high-order K error factors with high similarity.

### Advantageous Effects of Example 2

In Example 2, information which can be used to specify the error factors increases by referring to the error dictionary in which the combinations of the feature quantities labeled with the error factors are stored. Accordingly, it is possible to estimate more detailed error factors such as inappropriate recipe parameters in the case of recipe-induced errors and defective portions in the case of hard-induced errors.

### Example 3

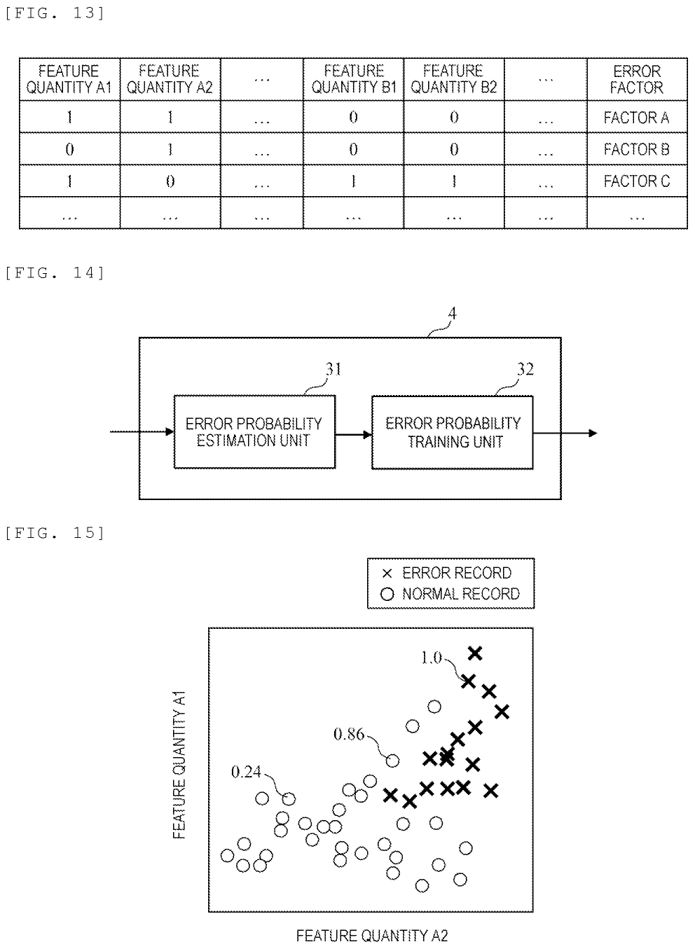

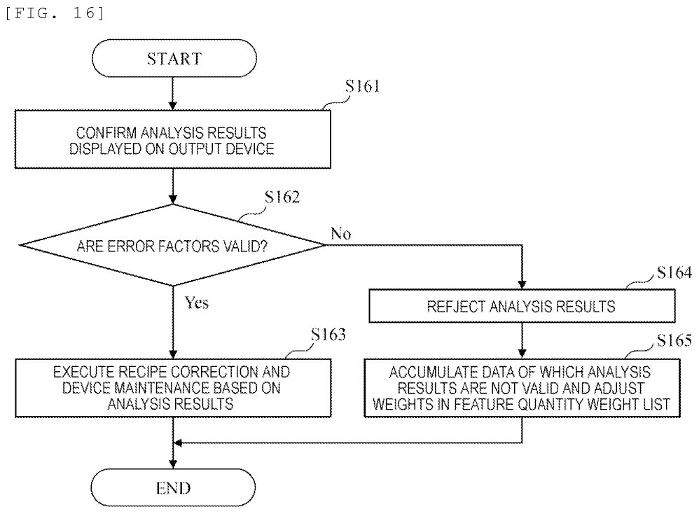

An error factor estimation device 100 according to Example 3 will be described with reference to FIGS. 14 and 15. As illustrated in FIG. 14, a model generating unit 4 of the error factor estimation device 100 according to Example 3 includes an error probability estimation unit 31 and an error probability training unit 32 unlike Examples 1 and 2.

The error probability estimation unit 31 estimates an error probability of a normal record which is not recorded as an error for the analysis target data 1. A method of estimating an error of a normal record will be described with reference to FIG. 14. As illustrated in FIG. 4, an error probability of an error record is 1.0. An error probability of a normal record is estimated based on a positional relationship with an error record in a feature quantity space. The error probability can be estimated from a model for predicting whether an error label is assigned, such as positive and unlabeled learning.

The error probability training unit 32 generates a model for training an error probability estimated by the error probability estimation unit 31. An estimation model for estimating probability is constructed using an algorithm in which a decision tree such as Random Forest or Gradient Boosting Tree is based or a machine training algorithm such as Neural Network.

### Advantageous Effects of Example 3

For example, for a measurement error in critical dimension-scanning electron microscope (CD-SEM), an error occurs or does not occur in data that has characteristics due to a minute difference in a device operation for each measurement time. To improve detection accuracy of an accidently occurring error record, a new detection rule for separating the accidently occurring error record as an error record is attempted to be learned by increasing feature quantities used for the training. Accordingly, in Example 3, with a model for training an error probability of each record, it is not necessary to execute modeling to identify a boundary between an accidently occurring error record and a normal record. Accordingly, since training of feature quantities with low relation with error factors is inhibited, it is possible to inhibit excessive training for the model. As a result, it is possible to improve extraction accuracy of the feature quantities contributing generalization performance of the model or estimation of the error factors and estimate the error factors with higher accuracy.

### Example 4

FIG. 16 is a flowchart illustrating a use example of an error factor estimation device 100 according to Example 4. In Example 4, a use example of the error factor estimation device 100 by a user will be described with reference to FIG. 16.

As a preparation stage before the error factor estimation device 100 is used, the analysis target data 1 of error factors is extracted from a database in which inspection results of one semiconductor inspection device 10 or of a plurality semiconductor inspection devices 10. As a method of extracting the analysis target data 1, a product name or a recipe name, a measurement period thereof, and the like are designated. The extracted analysis target data 1 is input to the error factor estimation device 100 and the analysis result 900 by the error factor estimation device 100 is displayed on the output device 7.

The user confirms the analysis result 900 (the error factors, the feature quantities contributing to the estimation of the error factors, and a trend of the feature quantities) displayed on the output device 7 (S161). Then, the user determines whether the error factors displayed on the output device 7 are valid (S162). When the user determines that the displayed error factors are valid (Yes in S162), the user corrects the recipe or executes device maintenance so that the error factors are solved based on the display analysis result 900 (S163).

When the user determines that the displayed error factors are not valid (No in S162), the user rejects the analysis result 900 (S164). Then, the user adjusts the weights of the feature quantities related to the rejected analysis result 900 so that the correct error factor is estimated (S165). That is, the computer system 200 executes an adjustment process of adjusting the weights of the feature quantities related to the ejected analysis result 900 to a relatively low level. The weights may be adjusted automatically using an existing optimization algorithm such as Bayes optimization or a metaheuristic algorithm or may be adjusted manually on the selection screen of FIG. 5. When an error dictionary is used as in Example 2, combinations of feature quantities stored in the error dictionary are compared with the combinations of the feature quantities with high usefulness calculated by the usefulness calculating unit 14 and adjustment is executed such that the weights of the matched feature quantities are high and the weights of the unmatched feature quantities are low. This is because the feature quantities unmatched with the error dictionary are not important in the estimation of the error factor and the feature quantities matched with the error dictionary are important in the estimation of the error factors. The weights may be adjusted whenever the analysis result 900 is rejected, or the rejected analysis result 900 may be accumulated and the weights may be adjusted collectively at any timing.

### Advantageous Effects of Example 4

By adjusting the weights of the feature quantities related to the analysis result 900 rejected by the user in this way, it is possible to improve estimation accuracy of the error factors in accordance with a product or a recipe to be used.

### Modified Examples

The present disclosure is not limited to the above-described embodiments and includes various modified examples. For example, the above-described embodiments have been described in detail to facilitate understanding of the present disclosure and all the configurations may not necessarily be included. Some of certain embodiments may be substituted with configurations of other embodiments. Configurations of other embodiments may be added to configurations of certain embodiments. Some of configurations of other embodiments can also be added to, deleted from or substituted with some of configurations of the embodiments.

For example, in the above Examples 1 to 4, the examples in which the error factor of the semiconductor inspection device 10 is estimated have been described, the error factors of errors to occur can also be estimated with a device other than the semiconductor inspection device 10.

The error factor estimation device 100 according to the above Examples 1 to 4 includes two feature quantity groups A and B and two models A5a and B5b, but the error factor estimation device 100 may be a device that includes one feature quantity group and one model trained with feature quantities of the feature quantity group.

In the above Examples 1 to 4, the error factors labeled to the feature quantities selected based on the usefulness have been acquired, but the error factors labeled to the feature quantities selected based on the contribution degrees may be acquired.

In the above Examples 1 to 4, the usefulness of each feature quantity extracted by the extraction unit 13 has been calculated, but the usefulness calculating unit 14 may calculate usefulness of all the feature quantities. In this case, the error factor acquisition unit 15 acquires the error factors based on the calculated usefulness with reference to the feature quantity error factor list 8.

### REFERENCE SIGNS LIST

1: analysis target data
2a: feature-quantity-group A generating unit
2b: feature-quantity-group B generating unit
3: feature quantity list storage unit
3a: feature quantity list A
3b: feature quantity list B
4: model generating unit
5a: model A
5b: model B
6: error factor estimation unit
7: output device
8: feature quantity error factor list
9: feature quantity weight list
10: semiconductor inspection device
11: contribution-degree-calculating unit
12a: contribution degree of feature group A
12b: contribution degree of feature group B
13: extraction unit
14: usefulness calculating unit
15: error factor acquisition unit
21: error factor acquisition unit
22: error dictionary
31: error probability estimation unit
32: error probability training unit
100: error factor estimation device

1. An error factor estimation device that estimates an error factor of an inspection result which becomes erroneous, the error factor estimation device comprising:
a computer system including one processor or a plurality of processors and one memory or a plurality of memories,
wherein the computer system executes
a first feature generating process of processing data including the inspection result collected from an inspection device and generating a plurality of feature quantities,
a model generating process of generating a first model for training a relationship between errors and the plurality of feature quantities generated through the first feature generating process,
a contribution degree calculating process of calculating a contribution degree indicating the degree of contribution of at least one of the plurality of feature quantities used for training for the first model to an output of the first model, and
an error factor acquisition process of acquiring error factors labeled with feature quantities or combinations of the feature quantities selected based on the contribution degree calculated through the contribution degree calculating process or usefulness calculated from the contribution degree.

2. The error factor estimation device according to claim 1, wherein the computer system
has an error factor list in which the feature quantities labeled with the error factors are stored, and
acquires an error factor labeled with the feature quantities selected based on the contribution degree or the usefulness with reference to the error factor list in the error factor acquisition process.

3. The error factor estimation device according to claim 1, wherein the computer system
has a dictionary in which the error factors are labeled with the combinations of the feature quantities, and
acquires an error factor labeled with a combination identical or similar to a combination of the feature quantities selected based on the contribution degree or the usefulness with reference to the dictionary in the error factor acquisition process.

4. The error factor estimation device according to claim 1, wherein the computer system
has a weight list in which the plurality of feature quantities are stored in association with weights set in the plurality of feature quantities, and
executes a usefulness calculating process of calculating the usefulness based on the contribution degree of the feature quantities and the weights stored in association with the feature quantities.

5. The error factor estimation device according to claim 4, wherein when a user rejects the error factor acquired through the error factor acquisition process, the computer system executes an adjustment process of adjusting the weight of the feature quantities labeled with the rejected error factor to a low level.

6. The error factor estimation device according to claim 4, wherein the computer system
executes an extraction process of extracting one feature quantity or a plurality of feature quantities with the large contribution degree among the plurality of feature quantities, and
calculates usefulness of the one feature quantity or the plurality of feature quantities extracted through the extraction process in the usefulness calculating process.

7. The error factor estimation device according to claim 1, wherein the computer system
executes a second feature generating process of processing data including the inspection result collected from the inspection device and generating a plurality of feature quantities different from the plurality of feature quantities generated through the first feature generating process,
generates a second model for training a relationship between errors and the plurality of feature quantities generated through the second feature generating process in the model generating process,
calculates the contribution degree of at least one of the plurality of feature quantities used for training the second model in the contribution degree calculating process, and
acquires error factors labeled with feature quantities or combinations of the feature quantities selected based on the contribution degree or the usefulness calculated through the contribution degree calculating process in the error factor acquisition process.

8. The error factor estimation device according to claim 1, wherein the computer system executes a selection process of selecting the plurality of feature quantities generated through the first feature generating process from the plurality of feature quantities.

9. The error factor estimation device according to claim 1, wherein the computer system executes a display control process of causing a display unit to display a list of the feature quantities or a trend of the feature quantities selected based on the contribution degree, the usefulness, or the error factors acquired through the error factor acquisition process.

10. The error factor estimation device according to claim 1, wherein, in the model generating process, a model for training a classification method of classifying error records and normal records using the plurality of feature quantities generated through the first feature generating process is generated.

11. The error factor estimation device according to claim 1, wherein in the model generating process, a model for training an error probability of each record estimated based on a positional relationship between error records and normal records in a feature space of the plurality of feature quantities is generated.

12. The error factor estimation device according to claim 1, wherein the feature quantity is an index related to a variation in an inspection result.

13. The error factor estimation device according to claim 12, wherein the feature index is at least one of
an index related to a variation in an inspection result in an identical device,
an index related to a variation in an inspection result in an identical measurement point,
an index related to a variation in an inspection result in an identical recipe,
an index related to a variation in an inspection result in an identical wafer, and
an index related to a variation in an inspection result in a measurement point using a reference image for identical pattern matching.

14. An error factor estimation method of estimating an error factor of an inspection result which becomes erroneous, the method comprising:
processing data including the inspection result collected from an inspection device and generating a plurality of feature quantities,
generating a first model for training a relationship between errors and the plurality of generated feature quantities;
calculating a contribution degree indicating the degree of contribution of at least one of the plurality of feature quantities used for training for the first model to an output of the first model, and
acquiring error factors labeled with feature quantities or combinations of the feature quantities selected based on the calculated contribution degree or usefulness calculated from the contribution degree.

15. The error factor estimation method according to claim 14, further comprising:
supplying an error factor list in which the feature quantities labeled with the error factors are stored, and
wherein the acquiring of the error factors includes acquiring an error factor labeled with the feature quantities selected based on the contribution degree or the usefulness with reference to the error factor list.

16. The error factor estimation method according to claim 14, further comprising:
supplying a dictionary in which the error factors are labeled with the combinations of the feature quantities, and
wherein the acquiring of the error factors includes acquiring an error factor labeled with a combination identical or similar to a combination of the feature quantities selected based on the contribution degree or the usefulness with reference to the dictionary.

17. A non-transitory computer-readable medium storing a program command for executing an error factor estimation method of estimating an error factor of an inspection result which becomes erroneous, wherein the error factor estimation method includes
processing data including the inspection result collected from an inspection device and generating a plurality of feature quantities,
generating a first model for training a relationship between errors and the plurality of generated feature quantities;
calculating a contribution degree indicating the degree of contribution of at least one of the plurality of feature quantities used for training for the first model to an output of the first model, and
acquiring error factors labeled with feature quantities or combinations of the feature quantities selected based on the calculated contribution degree or usefulness calculated from the contribution degree.

18. The computer-readable medium according to claim 17,
wherein the error factor estimation method further includes supplying an error factor list in which the feature quantities are labeled with the error factors, and
wherein the acquiring of the error factors includes acquiring an error factor labeled with the feature quantities selected based on the contribution degree or the usefulness with reference to the error factor list.

19. The computer-readable medium according to claim 17,
wherein the error factor estimation method further includes supplying a dictionary in which the error factors are labeled with the combinations of the feature quantities, and
wherein the acquiring of the error factors includes acquiring an error factor labeled with a combination identical or similar to a combination of the feature quantities selected based on the contribution degree or the usefulness with reference to the dictionary.
